(19) United States
(12) Patent Application Publication
(10) Pub. No.: US 2024/0258078 A1
(43) Pub. Date: Aug. 1, 2024

(54) PLASMA PROCESSING APPARATUS, ELECTROSTATIC CHUCK, AND PLASMA PROCESSING METHOD

(71) Applicant: Tokyo Electron Limited, Tokyo (JP)

(72) Inventor: Takahiko SATO, Miyagi (JP)

(73) Assignee: Tokyo Electron Limited, Tokyo (JP)

(21) Appl. No.: 18/427,838

(22) Filed: Jan. 31, 2024

(30) Foreign Application Priority Data
Jan. 31, 2023 (JP) 2023-012673

(51) Int. Cl. H01J 37/32; H01L 21/683

(52) U.S. Cl. CPC H01J 37/32568; H01J 37/32715; H01L 21/6833; H01J 2237/2007; H01J 2237/334

(57) ABSTRACT

There is a plasma processing apparatus comprising: a plasma processing chamber; an electrostatic chuck disposed on a base, and comprising a substrate mounting portion and an edge ring mounting portion; and at least one of a first power supply part that supplies power to the substrate mounting portion and a second power supply part that supplies power to the edge ring mounting portion, wherein the first power supply part comprises: a first electrode layer formed on the substrate mounting portion; a first adsorption electrode layer disposed under the first electrode layer; and a first bias power source connected to the first electrode layer, and wherein the second power supply part comprises: a second electrode layer formed on the edge ring mounting portion; a second adsorption electrode layer disposed under the second electrode layer; and a second bias power source connected to the second electrode layer.

### CROSS-REFERENCE TO RELATED APPLICATION

This application claims priority to Japanese Patent Application No. 2023-012673, filed on Jan. 31, 2023, the entire contents of which are incorporated herein by reference.

### TECHNICAL FIELD

The present disclosure relates to a plasma processing apparatus, an electrostatic chuck, and a plasma processing method.

### BACKGROUND

Japanese Laid-open Patent Publication No. 2020-205379 discloses an electrostatic chuck for supporting a substrate and an edge ring. A bias electrode, to which bias power for ion implantation is applied, is provided within the electrostatic chuck.

### SUMMARY

The present disclosure improves power efficiency in a plasma processing apparatus.

In accordance with an aspect of the present disclosure, there is a plasma processing apparatus comprising: a plasma processing chamber; a base disposed in the plasma processing chamber; an electrostatic chuck disposed on the base, and comprising a substrate mounting portion, and an edge ring mounting portion on which an edge ring surrounding a substrate mounted on the substrate mounting portion is mounted; and at least one of a first power supply part that supplies power to the substrate mounting portion and a second power supply part that supplies power to the edge ring mounting portion, wherein the first power supply part comprises: a first electrode layer formed on a substrate mounting surface of the substrate mounting portion; a first adsorption electrode layer disposed under the first electrode layer in the substrate mounting portion; and a first bias power source electrically connected to the first electrode layer, and wherein the second power supply part comprises: a second electrode layer formed on an edge ring mounting surface of the edge ring mounting portion; a second adsorption electrode layer disposed under the second electrode layer in the edge ring mounting portion; and a second bias power source electrically connected to the second electrode layer.

### BRIEF DESCRIPTION OF THE DRAWINGS

FIG. 1 is an explanatory diagram illustrating an example of the configuration of a plasma processing system.

FIG. 2 is a sectional view illustrating an example of the configuration of a plasma processing apparatus.

FIG. 3 is a sectional view illustrating an example of the configuration of a substrate support part.

FIGS. 4A and 4B are explanatory diagrams illustrating a method of controlling a sheath in an edge area of a substrate.

FIG. 5 is an explanatory diagram illustrating the arrangement of a first electrode layer on a seal band.

FIG. 6 is an explanatory diagram illustrating a circuit including a first adsorption power source and a second adsorption power source.

FIG. 7 is a sectional view illustrating a portion of the substrate support part when a base is formed of an insulating material.

FIG. 8 is a sectional view illustrating a portion of the substrate support part when the base is formed of the insulating material.

FIG. 9 is a sectional view illustrating a portion of the substrate support part when the base includes a conductive member.

FIG. 10 is a sectional view illustrating a portion of the substrate support part when the base includes the conductive member.

FIG. 11 is a sectional view illustrating a portion of the substrate support part when the base is formed of the insulating material.

FIG. 12 is a sectional view illustrating a portion of the substrate support part when the base is formed of the insulating material.

FIG. 13 is a plan view illustrating an arrangement of a first electrode layer and a second electrode layer.

FIG. 14 is an enlarged plan view illustrating a portion of FIG. 13.

FIG. 15 is a sectional view taken along line XV-XV of FIG. 14.

FIG. 16 is a plan view illustrating an arrangement of the first electrode layer and the second electrode layer.

FIG. 17 is a plan view illustrating an arrangement of the first electrode layer and the second electrode layer.

FIG. 18A-18C are explanatory diagrams illustrating an example of an adsorption sequence of an edge ring.

FIG. 19 is an explanatory diagram illustrating a first example of the adsorption sequence.

FIG. 20 is an explanatory diagram illustrating a second example of the adsorption sequence.

FIG. 21 is an explanatory diagram illustrating a third example of the adsorption sequence.

### DETAILED DESCRIPTION

In a process of manufacturing a semiconductor device, a semiconductor substrate (hereinafter referred to as a “substrate”) is subjected to plasma processing, for example, in a plasma processing apparatus. In the plasma processing apparatus, plasma is generated by exciting a process gas in a chamber, and the substrate supported by an electrostatic chuck is processed by the plasma.

In the plasma processing apparatus, improvement in power efficiency is required for the purpose of improving plasma processing productivity. Conventionally, in order to improve the efficiency of supplying bias power, for example, improvement has been made to increase capacitance between the substrate and a bias electrode. When the bias electrode is provided in the electrostatic chuck as disclosed in Japanese Laid-open Patent Publication No. 2020-205379, the thickness of a dielectric portion between the substrate and the bias electrode is reduced, thus achieving high capacitance and reducing a dielectric loss.

For example, when etching is performed as plasma processing, the above-mentioned increase in capacitance contributes to improving an etching rate. Further, when high capacitance is achieved, etching characteristics such as line width and selectivity are also improved, for example in the case of supplying square-wave bias power. Therefore, high capacitance is useful for plasma processing.

However, the thickness of the dielectric portion may not be sufficiently reduced in view of withstand voltage. For this reason, there is a limit to increase the capacitance. Therefore, there is room for improvement in power efficiency in plasma processing.

The present disclosure improves power efficiency in a plasma processing apparatus. Hereinafter, a plasma processing apparatus, an electrostatic chuck, and a plasma processing method according to this embodiment will be described with reference to the accompanying drawings. In this specification and the drawings, elements having substantially the same functions are designated by the same reference numerals, so that duplicated description thereof will be omitted.

### <Plasma Processing System>

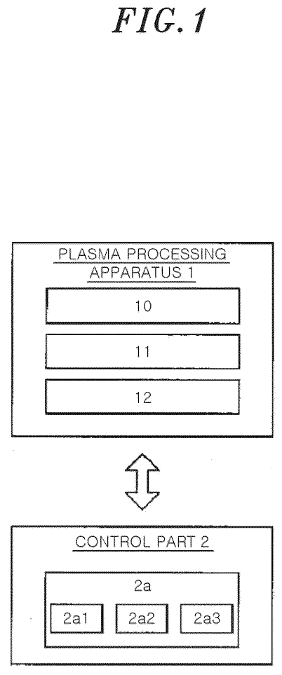

FIG. 1 is a diagram illustrating an example of the configuration of a plasma processing system. In an embodiment, the plasma processing system includes a plasma processing apparatus 1 and a control part 2. The plasma processing system is an example of the substrate processing system, and the plasma processing apparatus 1 is an example of the substrate processing apparatus. The plasma processing apparatus 1 includes a plasma processing chamber 10, a substrate support part 11, and a plasma generating part 12. The plasma processing chamber 10 has a plasma processing space. Further, the plasma processing chamber 10 has at least one gas supply port to supply at least one process gas to a plasma processing space, and at least one gas outlet to discharge gas from the plasma processing space. The gas supply port is connected to a gas supply part 20 that will be described later, and the gas outlet is connected to an exhaust system 40 that will be described later. A substrate support part 11 is disposed in the plasma processing space and has a substrate support surface to support a substrate.

The plasma generating part 12 is configured to generate plasma from at least one process gas supplied into the plasma processing space. The plasma formed in the plasma processing space may be Capacitively Coupled Plasma (CCP), Inductively Coupled Plasma (ICP), Electron-Cyclotron-resonance (ECR) plasma, Helicon Wave Plasma (HWP), or Surface Wave Plasma (SWP). Further, various types of plasma generating parts including an Alternating Current (AC) plasma generating part and a Direct Current (DC) plasma generating part may be used. In an embodiment, an AC signal (AC power) used in the AC plasma generating part has a frequency in the range of 100 kHz to 10 GHz. Therefore, the AC signal includes a Radio Frequency (RF) signal and a microwave signal. In an embodiment, the RF signal has a frequency in the range of 100 kHz to 150 MHz.

The control part 2 processes computer-executable instructions that cause the plasma processing apparatus 1 to execute various processes described in the present disclosure. The control part 2 may be configured to control each component of the plasma processing apparatus 1 to perform various processes described herein. In an embodiment, a portion or entirety of the control part 2 may be included in the plasma processing apparatus 1. The control part 2 may include a processing part 2a1, a storage part 2a2, and a communication interface 2a3. The control part 2 may be implemented by, for example, a computer 2a. The processing part 2a1 may be configured to perform various control operations by reading a program from the storage part 2a2 and executing the read program. This program may be previously stored in the storage part 2a2 or may be acquired through a medium when necessary. The acquired program is stored in the storage part 2a2, and is read from the storage part 2a2 by the processing part 2a1 to be executed. The medium may be various storage media that may be read by the computer 2a, or may be a communication line connected to the communication interface 2a3. The processing part 2a1 may be a Central Processing Unit (CPU). The storage part 2a2 may include Random Access Memory (RAM), Read Only Memory (ROM), Hard Disk Drive (HDD), Solid State Drive (SSD), or a combination thereof. The communication interface 2a3 may communicate with the plasma processing apparatus 1 through the communication line such as a Local Area Network (LAN).

### <Plasma Processing Apparatus>

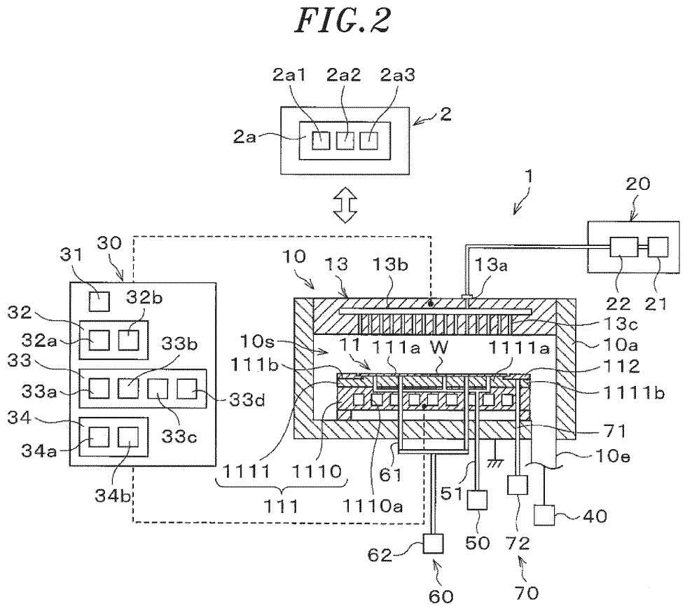

Hereinafter, an example of the configuration of a capacitively coupled plasma processing apparatus as an example of the plasma processing apparatus 1 will be described. FIG. 2 is a diagram illustrating the example of the configuration of a capacitively coupled plasma processing apparatus.

The capacitively coupled plasma processing apparatus 1 includes a plasma processing chamber 10, a gas supply part 20, a power source 30, and an exhaust system 40. Further, the plasma processing apparatus 1 includes a substrate support part 11 and a gas introduction part. The gas introduction part is configured to introduce at least one process gas into the plasma processing chamber 10. The gas introduction part includes a shower head 13. The substrate support part 11 is disposed in the plasma processing chamber 10. The shower head 13 is disposed above the substrate support part 11. In an embodiment, the shower head 13 forms at least a portion of a ceiling of the plasma processing chamber 10. The plasma processing chamber 10 has a plasma processing space 10s defined by the shower head 13, a sidewall 10a of the plasma processing chamber 10, and the substrate support part 11. The plasma processing chamber 10 is grounded. The shower head 13 and the substrate support part 11 are electrically insulated from a housing of the plasma processing chamber 10.

The substrate support part 11 includes a main body 111 and an edge ring 112. The main body 111 has a substrate mounting surface 111a that is a central area to mount and support a substrate W thereon, and an edge ring mounting surface 111b that is an annular area to mount and support the edge ring 112. A wafer is an example of the substrate W. The edge ring mounting surface 111b of the main body 111 surrounds the substrate mounting surface 111a of the main body 111 in a plan view. The substrate W is mounted on the substrate mounting surface 111a of the main body 111, and the edge ring 112 is mounted on the edge ring mounting surface 111b of the main body 111 to surround the substrate W on the substrate mounting surface 111a of the main body 111.

In an embodiment, the main body 111 includes a base 1110 and an electrostatic chuck 1111. The base 1110 includes a conductive member. The conductive member of the base 1110 may serve as a lower electrode. The electrostatic chuck 1111 is disposed above the base 1110. The electrostatic chuck 1111 is provided with a substrate mounting portion 1111a and an edge ring mounting portion 1111b. In the present disclosure, the substrate mounting portion 1111a and the edge ring mounting portion 1111b form a dielectric portion, and are formed of ceramic, for example. The substrate mounting portion 1111a has the substrate mounting surface 111a, and mounts the substrate W thereon. The edge ring mounting portion 1111b has the edge ring mounting surface 111b, and mounts the edge ring thereon. The edge ring mounting portion 1111b is disposed to surround the substrate mounting portion 1111a. The edge ring mounting surface 111b is formed at a lower position than the substrate mounting surface 111a.

Further, another member surrounding the electrostatic chuck 1111, such as an annular electrostatic chuck or an annular insulation member, may have the edge ring mounting surface 111b. In this case, the edge ring 112 may be disposed on the annular electrostatic chuck or the annular insulation member, and may be disposed on both the electrostatic chuck 1111 and the annular insulation member.

The edge ring 112 includes one or more members. The edge ring 112 is formed of a conductive material or an insulating material. Further, at least one cover ring may be provided at the outside of the edge ring 112 to surround the edge ring 112. The cover ring is formed of an insulating material.

Further, the substrate support part 11 may include a temperature control module configured to adjust at least one of the electrostatic chuck 1111, the edge ring 112, and the substrate W to a target temperature. The temperature control module may include a heater, a heat transfer medium, a flow path 1110a, or a combination thereof. A heat transfer fluid such as brine or gas flows through the flow path 1110a. In an embodiment, the flow path 1110a is formed in the base 1110, and one or more heaters are disposed within the substrate mounting portion 1111a and the edge ring mounting portion 1111b of the electrostatic chuck 1111. Further, the substrate support part 11 may include a heat transfer gas supply part 50 configured to supply heat transfer gas to a gap (hereinafter referred to as a “first heat transfer space”) between the back surface of the substrate W and the substrate mounting surface 111a, or a gap (hereinafter referred to as a “second heat transfer space”) between the back surface of the edge ring 112 and the edge ring mounting surface 111b. The heat transfer gas supply part 50 supplies the heat transfer gas to the first and second heat transfer spaces via the heat transfer gas supply path 51.

A first lifter 60 is provided under the substrate support part 11 to raise and lower the substrate W with respect to the substrate mounting portion 1111a. The first lifter 60 has a first lifter pin 61 and a drive part 62. The first lifter pin 61 is connected to the drive part 62 to be movable up and down.

Further, a second lifter 70 is provided under the substrate support part 11 to raise and lower the edge ring 112 with respect to the edge ring mounting portion 1111b. The second lifter 70 has a second lifter pin 71 and a drive part 72. The second lifter pin 71 is connected to the drive part 72 to be movable up and down.

The shower head 13 is configured to introduce at least one process gas from the gas supply part 20 into the plasma processing space 10s. The shower head 13 has at least one gas supply port 13a, at least one gas diffusion chamber 13b, and a plurality of gas introduction ports 13c. The process gas supplied to the gas supply port 13a passes through the gas diffusion chamber 13b and then is introduced from a plurality of gas introduction ports 13c into the plasma processing space 10s. Further, the shower head 13 includes at least one upper electrode. In addition to the shower head 13, the gas introduction part may include one or more side gas injectors (SGI) installed in one or more openings formed in the side wall 10a.

The gas supply part 20 may include at least one gas source 21 and at least one flow controller 22. In an embodiment, the gas supply part 20 is configured to supply at least one process gas from a respective gas source 21 through a respective flow controller 22 to the shower head 13. Each flow controller 22 may include, for example, a mass flow controller or a pressure-controlled flow controller. Further, the gas supply part 20 may include at least one flow modulation device that modulates or pulses the flow rate of at least one process gas.

The power source 30 includes a source RF power source 31 as an example of the plasma generating power source, a bias RF power source 32 as an example of the bias power source, and an adsorption power source 33. The source RF power source 31 and the bias RF power source 32 are coupled to the plasma processing chamber 10 via at least one impedance matching circuit. The adsorption power source 33 is coupled to the plasma processing chamber 10.

The source RF power source 31 is electrically connected to at least one lower electrode and/or at least one upper electrode via at least one impedance matching circuit, and is configured to generate a plasma generating source RF signal (source RF power). In an embodiment, the source RF signal has a frequency in the range of 10 MHz to 150 MHz. In an embodiment, the source RF power source 31 may be configured to generate a plurality of source RF signals having different frequencies. One or more generated source RF signals are supplied to at least one lower electrode and/or at least one upper electrode. Thereby, plasma is generated from at least one process gas supplied to the plasma processing space 10s. Therefore, the source RF power source 31 may function as at least a portion of the plasma generating part 12.

In an embodiment, the bias RF power source 32 includes a first bias RF power source 32a and a second bias RF power source 32b. The first bias RF power source 32a is electrically connected to a first electrode layer 210, which will be described later, via at least one impedance matching circuit, and is configured to generate a first bias RF signal (first bias RF power). The second bias RF power source 32b is electrically connected to a second electrode layer 212, which will be described later, via at least one impedance matching circuit, and is configured to generate a second bias RF signal (second bias RF power). The frequency of each of the first and second bias RF signals may be identical to or different from that of the source RF signal. In an embodiment, each of the first and second bias RF signals has a frequency lower than that of the source RF signal. In an embodiment, each of the first and second bias RF signals has a frequency in the range of 100 kHz to 60 MHz. In an embodiment, the first bias RF power source 32a and the second bias RF power source 32b may be configured to generate a plurality of bias RF signals having different frequencies. One or more first bias RF signals generated by the first bias RF power source 32a are supplied to the first electrode layer 210 that will be described later, and one or more second bias RF signals generated by the second bias RF power source 32b are supplied to the second electrode layer 212 that will be described later. Thereby, a bias potential may be generated in the substrate W, and ion components in the generated plasma may be attracted/drawn into the substrate W. Further, in various embodiments, at least one of the source RF signal and the first and second bias RF signals may be pulsed.

In an embodiment, the adsorption power source 33 includes a first adsorption power source 33a, a second adsorption power source 33b, a third adsorption power source 33c, and a fourth adsorption power source 33d.

The first adsorption power source 33a is electrically connected to the first electrode layer 210 that will be described later, and is configured to generate the first adsorption DC signal (first adsorption power). The generated first adsorption DC signal is supplied to the first electrode layer 210 that will be described later. The second adsorption power source 33b is electrically connected to a first adsorption electrode layer 211 that will be described later, and is configured to generate the second adsorption DC signal (second adsorption power). The generated second adsorption DC signal is supplied to the first adsorption electrode layer 211 that will be described later. An electrostatic force generated by the first and second adsorption powers allows the substrate W to be held on the substrate mounting surface 111a. Further, the first adsorption power source 33a may be omitted.

The third adsorption power source 33c is electrically connected to the second electrode layer 212 that will be described later, and is configured to generate the third adsorption DC signal (third adsorption power). The generated third adsorption DC signal is supplied to the second electrode layer 212 that will be described later. The fourth adsorption power source 33d is electrically connected to a second adsorption electrode layer 213 that will be described later, and is configured to generate the fourth adsorption DC signal (fourth adsorption power). The generated fourth adsorption DC signal is supplied to the second adsorption electrode layer 213 that will be described later. An electrostatic force generated by the third and fourth adsorption powers allows the edge ring 112 to be held on the edge ring mounting surface 111b. Further, the third adsorption power source 33c may be omitted.

Further, the power source 30 may include a DC power source 34 coupled to the plasma processing chamber 10. The DC power source 34 includes a first DC power source 34a and a second DC power source 34b. In an embodiment, the first DC power source 34a is electrically connected to at least one lower electrode, and is configured to generate a first DC signal. The generated first DC signal is applied to at least one lower electrode. In an embodiment, the second DC power source 34b is electrically connected to at least one upper electrode, and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform that is rectangular, trapezoidal, triangular, or a combination thereof. In an embodiment, a waveform generating part for generating a sequence of voltage pulses from the DC signal is connected between the first DC power source 34a and at least one lower electrode. Therefore, the first DC power source 34a and the waveform generating part constitute a voltage pulse generating part. When the second DC power source 34b and the waveform generating part constitute the voltage pulse generating part, the voltage pulse generating part is connected to at least one upper electrode. The voltage pulse may have positive or negative polarity. Further, the sequence of voltage pulses may include one or more positive voltage pulses and one or more negative voltage pulses within one period. The first and second DC power sources 34a and 34b may be provided in addition to the source RF power source 31 and the bias RF power source 32, and may be provided in place of the bias RF power source 32.

The exhaust system 40 may be connected to a gas outlet 10e that is provided at a bottom of the plasma processing chamber 10, for example. The exhaust system 40 may include a pressure regulating valve and a vacuum pump. Pressure in the plasma processing space 10s is regulated by the pressure regulating valve. The vacuum pump may include a turbo molecular pump, a dry pump, or a combination thereof.

### <Substrate Support Part>

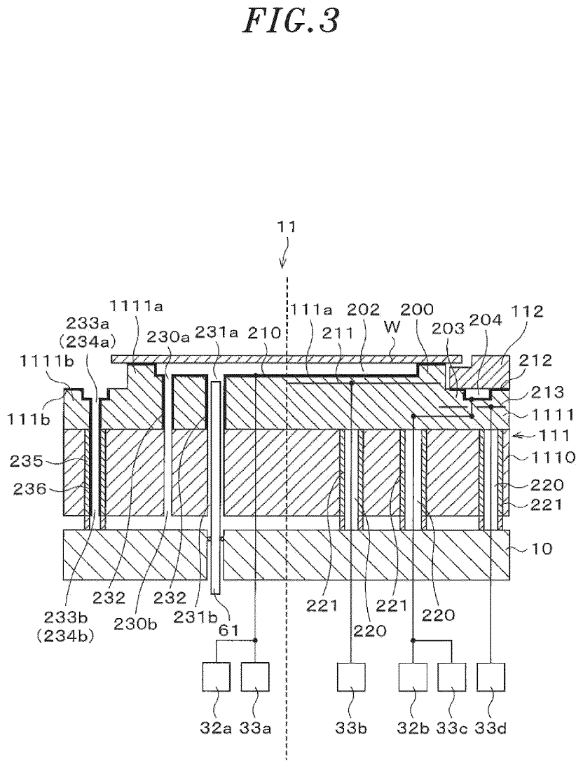

Next, the configuration of the above-mentioned substrate support part 11 will be described with reference to FIG. 3. FIG. 3 is a sectional view schematically illustrating an example of the configuration of the substrate support part 11. In FIG. 3, the right side of a center dotted line mainly shows the electrode layer, while the left side of the center dotted line mainly shows a through hole.

The substrate mounting surface 111a of the substrate mounting portion 1111a includes a seal band 200 and a plurality of dots 201. In FIG. 3, the illustration of the dots 201 is omitted. The seal band 200 is formed in an annular shape on the outer peripheral side of the substrate mounting surface 111a. The seal band 200 seals the first heat transfer space 202 between the back surface of the substrate W and the substrate mounting surface 111a. The plurality of dots 201 may be disposed on the inside of the seal band 200. Each dot 201 has a cylindrical shape. The seal band 200 and the plurality of dots 201 have upper surfaces that are formed level at the same height, and contact the substrate W when the substrate W is mounted on the substrate mounting surface 111a.

The edge ring mounting surface 111b of the edge ring mounting portion 1111b is provided with a seal band 203. The seal band 203 is formed in an annular shape on the inside and outside of the edge ring mounting surface 111b. The seal band 203 seals a second heat transfer space 204 between the back surface of the edge ring 112 and the edge ring mounting surface 111b. The seal band 203 has a flat upper surface, and contacts the edge ring 112 when the edge ring 112 is mounted on the edge ring mounting surface 111b.

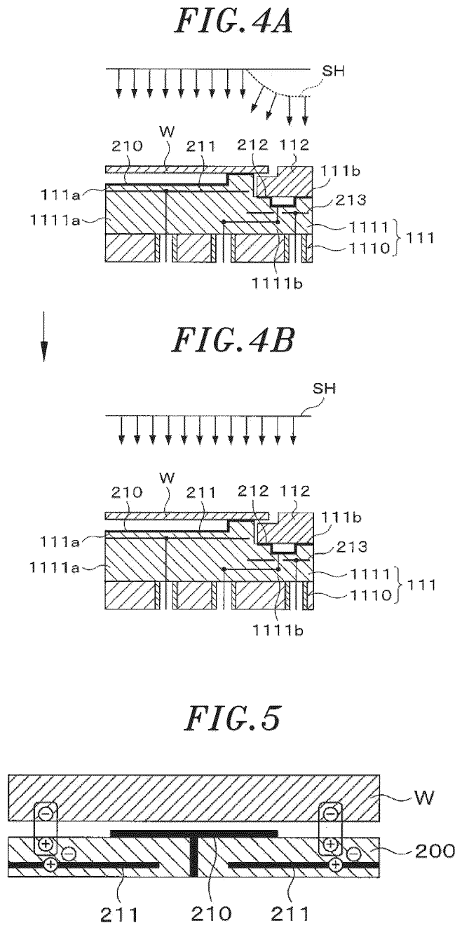

The first electrode layer 210 is formed on the substrate mounting surface 111a of the substrate mounting portion 1111a. That is, when the substrate W is mounted on the substrate mounting surface 111a, the first electrode layer 210 contacts the substrate W to be electrically conductive thereto. The first bias RF power source 32a and the first adsorption power source 33a are electrically connected to the first electrode layer 210. In the example of FIG. 3, the first electrode layer 210 is formed on the entire surface of the substrate mounting surface 111a in order to facilitate understanding of the description, but is actually formed in a desired pattern. The same applies to examples shown in FIGS. 4, 7 to 12, and 18. The specific arrangement of the first electrode layer 210 will be described later. Further, the first electrode layer 210 corresponds to the first bias electrode layer in the present disclosure.

The first adsorption electrode layer 211 is formed under the first electrode layer 210 in the substrate mounting portion 1111a. The second adsorption power source 33b is electrically connected to the first adsorption electrode layer 211.

The first electrode layer 210, the first adsorption electrode layer 211, the first bias RF power source 32a, the first adsorption power source 33a, and the second adsorption power source 33b constitute a first power supply part of the present disclosure, which supplies power to the substrate mounting portion 1111a. Further, the first electrode layer 210 and the first adsorption electrode layer 211 constitute a first electrode part of the present disclosure, which is provided on the substrate mounting portion 1111a.

The second electrode layer 212 is formed on the edge ring mounting surface 111b of the edge ring mounting portion 1111b. That is, when the edge ring 112 is mounted on the edge ring mounting surface 111b, the second electrode layer 212 contacts the edge ring 112 to be electrically conductive thereto. The second bias RF power source 32b and the third adsorption power source 33c are electrically connected to the second electrode layer 212. In the example of FIG. 3, the second electrode layer 212 is formed on the entire surface of the edge ring mounting surface 111b in order to facilitate understanding of the description, but is actually formed in a desired pattern. The same applies to examples shown in FIGS. 4, 7 to 12, and 18. The specific arrangement of the second electrode layer 212 will be described later. Further, the second electrode layer 212 corresponds to the second bias electrode layer in the present disclosure.

The second adsorption electrode layer 213 is formed under the second electrode layer 212 in the edge ring mounting portion 1111b. The fourth adsorption power source 33d is electrically connected to the second adsorption electrode layer 213.

The second electrode layer 212, the second adsorption electrode layer 213, the second bias RF power source 32b, the third adsorption power source 33c, and the fourth adsorption power source 33d constitute a second power supply part of the present disclosure, which supplies power to the edge ring mounting portion 1111b. Further, the second electrode layer 212 and the second adsorption electrode layer 213 constitute a second electrode part of the present disclosure, which is provided on the edge ring mounting portion 1111b.

A through hole 220 is formed in the base 1110 to insert a power supply line of each of the above-mentioned power sources 32a to 32b and 33a to 33d therein. An insulating film 221 is formed on the inner surface of the through hole 220. The material of the insulating film 221 is not limited to a specific material but may use glass. In the example shown in FIG. 3, the insulating film 221 is formed in the through hole 220, but the present disclosure is not limited thereto. An insulating sleeve made of ceramics or the like may be inserted into the through hole 220.

A first heat transfer gas supply hole 230a as an example of the first through hole is formed in the substrate mounting portion 1111a. The first heat transfer gas supply hole 230a penetrates the substrate mounting surface 111a in a thickness direction. A first heat transfer gas supply hole 230b is also formed in the base 1110. The first heat transfer gas supply hole 230a and the first heat transfer gas supply hole 230b are continuously formed, and are included in the above-mentioned heat transfer gas supply path 51. Further, the first heat transfer gas supply holes 230a and 230b communicate with the heat transfer gas supply part 50. Further, in the illustrated example, the first heat transfer gas supply hole 230a extends in the thickness direction of the substrate mounting portion 1111a, but any path of the first heat transfer gas supply hole 230a is possible. For example, a horizontal path may be included. Further, the first heat transfer gas supply hole 230b penetrates the base 1110, but the path of the first heat transfer gas supply hole 230b is optional. The heat transfer gas supplied from the heat transfer gas supply part 50 is supplied through the first heat transfer gas supply holes 230a and 230b to the first heat transfer space 202 between the back surface of the substrate W and the substrate mounting surface 111a.

Further, a first pin insert hole 231a as an example of the first through hole is formed in the substrate mounting portion 1111a. The first pin insert hole 231a penetrates the substrate mounting surface 111a in the thickness direction. A first pin insert hole 231b is also formed in the base 1110. The first pin insert hole 231b penetrates the base 1110 in the thickness direction. The first pin insert hole 231a and the first pin insert hole 231b are continuously formed, and the first lifter pin 61 is inserted into the first pin insert holes 231a and 231b.

A first conductive film 232 is formed on the inner surface of the first heat transfer gas supply hole 230a to be electrically conductive to the first electrode layer 210. The first conductive film 232 is also formed on the inner surface of the first pin insert hole 231a to be electrically conductive to the first electrode layer 210. The first conductive films 232 are short-circuited and electrically connected to the base 1110. No conductive film is formed on the inner surface of the first heat transfer gas supply hole 230b and the inner surface of the first pin insert hole 231b.

A second heat transfer gas supply hole 233a as an example of the second through hole is formed in the edge ring mounting portion 1111b. The second heat transfer gas supply hole 233a penetrates the edge ring mounting surface 111b in a thickness direction. A second heat transfer gas supply hole 233b is also formed in the base 1110. The second heat transfer gas supply hole 233a and the second heat transfer gas supply hole 233b are continuously formed, and are included in the above-mentioned heat transfer gas supply path 51. Further, the second heat transfer gas supply holes 233a and 233b communicate with the heat transfer gas supply part 50. Further, in the illustrated example, the second heat transfer gas supply hole 233a extends in the thickness direction of the edge ring mounting portion 1111b, but any path of the second heat transfer gas supply hole 233a is possible. For example, a horizontal path may be included. Further, the second heat transfer gas supply hole 233b penetrates the base 1110, but the path of the second heat transfer gas supply hole 233b is optional. The heat transfer gas supplied from the heat transfer gas supply part 50 is supplied through the second heat transfer gas supply holes 233a and 233b to the second heat transfer space 204 between the back surface of the edge ring 112 and the edge ring mounting surface 111b.

Further, a second pin insert hole 234a as an example of the second through hole is formed in the edge ring mounting portion 1111b. The second pin insert hole 234a penetrates the edge ring mounting surface 111b in the thickness direction. A second pin insert hole 234b is also formed in the base 1110. The second pin insert hole 234b penetrates the base 1110 in the thickness direction. The second pin insert hole 234a and the second pin insert hole 234b are continuously formed, and the second lifter pin 71 is inserted into the second pin insert holes 234a and 234b.

An insulating film 235 is formed on the inner surface of the second heat transfer gas supply hole 233b and the inner surface of the second pin insert hole 234b. On the inner surfaces of the second heat transfer gas supply hole 233a and the second heat transfer gas supply hole 233b (insulating film 235), a second conductive film 236 that is electrically conductive to the second electrode layer 212 is formed from an upper end of the second heat transfer gas supply hole 233a to a lower end of the second heat transfer gas supply hole 233b. Similarly, on the inner surfaces of the second pin insert hole 234a and the second pin insert hole 234b (insulating film 235), the second conductive film 236 that is electrically conductive to the second electrode layer 212 is formed from an upper end of the second pin insert hole 234a to a lower end of the second pin insert hole 234b. In the example shown in FIG. 3, the insulating film 235 is formed in the second heat transfer gas supply hole 233a and the second pin insert hole 234b, but the present disclosure is not limited thereto. An insulating sleeve made of ceramics or the like may be inserted into the second heat transfer gas supply hole 233a and the second pin insert hole 234b.

### <Direct Supply of Bias RF Power (Measures to Improve Power Efficiency)>

According to this embodiment, the first electrode layer 210 is provided on the substrate mounting surface 111a of the substrate mounting portion 1111a, and the first electrode layer 210 and the substrate W contact each other. Further, the first bias RF power source 32a is connected to the first electrode layer 210. Therefore, the first bias RF power is directly supplied (electrically connected) from the first bias RF power source 32a via the first electrode layer 210 to the substrate W. As a result, since no dielectric loss occurs, power loss can be reduced, and power efficiency in plasma processing can be improved.

Further, the second electrode layer 212 is provided on the edge ring mounting surface 111b of the edge ring mounting portion 1111b, and the second electrode layer 212 and the edge ring 112 contact each other. Further, the second bias RF power source 32b is connected to the second electrode layer 212. Therefore, the second bias RF power is directly supplied (electrically connected) from the second bias RF power source 32b via the second electrode layer 212 to the edge ring 112. As a result, since no dielectric loss occurs, power loss can be reduced, and power efficiency in plasma processing can be improved.

Since the currents of the first and second bias RF powers flow through the surface of the first electrode layer 210 and the surface of the second electrode layer 212, respectively, due to the skin effect, each of the first electrode layer 210 and the second electrode layer 212 may be a thin structure, such as a conductive film. Further, any method may be used to manufacture the first and second electrode layers 210 and 212 such as the conductive film. For example, the first and second electrode layers 210 and 212 may be manufactured through surface treatment such as plating. Further, layered conductive ceramics or the like may be stacked, or plate-like conductive ceramics or the like may be bonded together.

Although the plasma processing apparatus 1 of this embodiment includes both the first electrode layer 210 and the second electrode layer 212, either of them may be omitted. For example, when the first electrode layer 210 is omitted and only the second electrode layer 212 is provided, the first bias RF power source 32a is connected to the bias electrode provided in the substrate mounting portion 1111a in place of the first electrode layer 210, and the first adsorption power source 33a is omitted. Further, for example, when the second electrode layer 212 is omitted and only the first electrode layer 210 is provided, the second bias RF power source 32b is connected to the bias electrode provided in the edge ring mounting portion 1111b in place of the second electrode layer 212, and the third adsorption power source 33c is omitted.

### (Suppression of Residual Adsorption Force)

Conventionally, since the electrode is provided in the electrostatic chuck, it is impossible to directly control the potential of the substrate. As a result, when the substrate is removed from the electrostatic chuck, a residual adsorption force may be generated due to the residual charge on the substrate. On the other hand, according to this embodiment, since the first electrode layer 210 and the substrate W are electrically conductive to each other, the potential of the substrate W may be directly controlled. For example, when the potential of the substrate W is connected to a ground potential, both the first electrode layer 210 and the substrate W become the ground potential, and no residual charge is generated between the first electrode layer 210 and the substrate W. Therefore, the residual adsorption force that acts when the substrate W is removed from the substrate mounting portion 1111a of the electrostatic chuck 1111 can be reduced.

Similarly, since the second electrode layer 212 and the edge ring 112 are electrically conductive to each other, the potential of the edge ring 112 may be directly controlled. For example, when the potential of the edge ring 112 is connected to the ground potential, both the second electrode layer 212 and the edge ring 112 become the ground potential, and no residual charge is generated between the second electrode layer 212 and the edge ring 112. Therefore, the residual adsorption force that acts when the edge ring 112 is removed from the edge ring mounting portion 1111b of the electrostatic chuck 1111 can be reduced.

(Edge Ring Adsorption when Plasma is not Generated)

The edge ring 112 needs to be held on the edge ring mounting portion 1111b of the electrostatic chuck 1111 by adsorption not only when the plasma is generated but also when the plasma is not generated. Conventionally, a bipolar adsorption electrode is provided in the electrostatic chuck to hold the edge ring by adsorption when the plasma is not generated. In this regard, according to this embodiment, the third adsorption power source 33c is connected to the second electrode layer 212, and the fourth adsorption power source 33d is connected to the second adsorption electrode layer 213. Therefore, the third adsorption power supplied to the second electrode layer 212 and the fourth adsorption power supplied to the second adsorption electrode layer 213 may adsorb and hold the edge ring 112 even when the plasma is not generated.

### (Independent Control of Second Bias RF Power)

In the case of directly supplying the first bias RF power to the substrate W, a sheath is formed to cover the substrate W. At this time, as shown in FIG. 4(a), ions are incident on the edge area of the substrate W from a direction that is not perpendicular to the substrate mounting surface 111a. Specifically, for example, when the edge ring 112 wears out and its thickness decreases, the thickness of the sheath SH decreases in the edge area of the substrate W, and the shape of the sheath SH changes to a downwardly convex shape.

Therefore, in order to suppress the oblique incidence of the ions, as shown in FIG. 4(b), the second bias RF power needs to be supplied to the edge ring 112 to lift and flatten the sheath SH in the edge area of the substrate W.

According to this embodiment, since the second bias RF power may be independently controlled via the second electrode layer 212, a tilt angle in the substrate W may be controlled. That is, the second bias RF power acts as a tilt control knob. The tilt angle is the inclination (angle) of a recess formed by etching with respect to the thickness direction of the substrate W, in the edge area of the substrate W. The tilt angle is approximately the same as the inclination (ion incidence angle) of the direction of ion incidence into the edge area of the substrate W with respect to a vertical direction.

In particular, when using first and second square-wave bias powers in place of the first and second bias RF powers, as the bias power, it is useful to independently control the first and second square-wave bias powers. The first square-wave bias power is supplied, for example, from the first DC power source 34a through the first electrode layer 210 to the substrate W. The second square-wave bias power is supplied, for example, from the second DC power source 34b through the second electrode layer 212 to the edge ring 112. Here, in the case of the square wave, the first square-wave bias power and the second square-wave bias power have a rise time and fall time of the waveform that is short and steep. Therefore, if the timing of supplying the first square-wave bias power and the timing of supplying the second square-wave bias power are even slightly different, a potential difference is likely to occur between the substrate W and the edge ring 112. In other words, in the case of the square wave, it is important to synchronize the potential of the substrate W and the potential of the edge ring 112 in controlling the tilt angle. In this regard, according to this embodiment, the supply timings of the first and second square-wave bias powers can be appropriately synchronized and the tilt angle can be appropriately controlled by independently controlling the first and second square-wave bias powers.

When the second bias RF power is independently controlled, the power supply line for supplying the second bias RF power to the second electrode layer 212 needs to be insulated from the power supply line of the first bias RF power or the like or the base 1110. Therefore, as described above, the insulating film 221 is formed on the inner surface of the through hole 220 into which the second bias RF power supply line is inserted.

### (Ion Implantation Control Using Square-Wave Bias Power)

Here, when the first and second square-wave bias powers are used as the bias power as described above, a state in which a large bias voltage is applied to the substrate W and the edge ring 112 continues for a long time because the rise time and fall time of the square wave are steep. Therefore, since ions are accelerated and incident on the substrate W, there is an advantage that a plasma processing rate such as an etching rate can be improved.

Further, according to this embodiment, since there is no influence of capacitance between the substrate W and the first electrode layer 210 and between the edge ring 112 and the second electrode layer 212, the first and second square-wave bias powers may be supplied to the substrate W and the edge ring 112 in an ideal state. Conventionally, improvement has been made to increase the capacitance between the substrate and the bias electrode as described above. This is to suppress a reduction in etching rate due to a reduction in potential difference between the substrate and the plasma. In a conventional configuration, since the bias electrode is provided in the electrostatic chuck, capacitance occurs between the substrate and the bias electrode. When the capacitance is small, ions are drawn into the substrate, which rapidly reduces the potential difference between the substrate and the plasma, resulting in a rapid decrease in etching rate. Therefore, improvement has been made to suppress the decrease in etching rate by increasing the capacitance and increasing time for the potential difference between the substrate and the plasma to decrease. On the other hand, according to this embodiment, since the first electrode layer 210 is formed on the substrate mounting surface 111a and the second electrode layer 212 is formed on the edge ring mounting surface 111b, there is no influence of capacitance between the substrate W and the first electrode layer 210 and between the edge ring 112 and the second electrode layer 212. Therefore, the first and second square-wave bias powers can be supplied to the substrate W and the edge ring 112 in the ideal state, and plasma processing rates such as the etching rate is improved.

### <Measures Against Adsorption-Force Reduction Due to Direct Power Supply>

For example, a conventional Coulomb-type electrostatic chuck adsorbs the substrate as follows. First, the dielectric portion of the electrostatic chuck is polarized by the voltage applied to the adsorption electrode in the electrostatic chuck. For example, if the adsorption electrode is controlled to have a positive potential, a negative charge is biased toward the adsorption electrode side in the electrostatic chuck, and a positive charge is biased toward a surface side (substrate side). Next, it is attracted by the biased charges, so electrons are supplied from the plasma to the substrate and the substrate is negatively charged. Then, the Coulomb force acts due to the potential difference between the surface of the electrostatic chuck (positive charge) and the back surface of the substrate (negative charge), so the substrate is adsorbed on the electrostatic chuck.

In this regard, when the first electrode layer 210 is formed on the substrate mounting surface 111a of the electrostatic chuck 1111 according to this embodiment, charges are paired between the substrate mounting surface 111a and the first electrode layer 210, and there is no potential difference between the substrate mounting surface 111a and the substrate W. In this case, the Coulomb force does not act, and the adsorption force on the first electrode layer 210 decreases. For the same reason, when the second electrode layer 212 is formed on the edge ring mounting surface 111b of the electrostatic chuck 1111, the adsorption force on the second electrode layer 212 is reduced.

### (Arrangement Adjustment of First and Second Electrode Layers)

In order to suppress the decrease in the adsorption force, it is preferable that the first electrode layer 210 is not provided on the entire surface of the substrate mounting surface 111a. In detail, the first electrode layer 210 preferably has an area that does not overlap the first adsorption electrode layer 211 in a plan view. In this case, in the above-mentioned area, the Coulomb force may be applied by the second adsorption power supplied to the first adsorption electrode layer 211, so the substrate W may be appropriately adsorbed and held on the substrate mounting surface 111a.

Further, in view of suppressing the decrease in the adsorption force, it is preferable that the back surface of the substrate W and the substrate mounting surface 111a contact each other around the first electrode layer 210 contacting the substrate W. For example, when the first electrode layer 210 is provided on the upper surface of the seal band 200 of the substrate mounting surface 111a as shown in FIG. 5, the first electrode layer 210 is provided at a center of the upper surface of the seal band 200 in a side view. Then, the Coulomb force acts on the inner peripheral side and outer peripheral side of the first electrode layer 210 on the upper surface of the seal band 200, i.e., on the area in which no first electrode layer 210 is provided.

Specifically, first, when the second adsorption power is supplied to the first adsorption electrode layer 211, the negative charge is biased toward the first adsorption electrode layer 211 of the dielectric portion of the electrostatic chuck 1111 on the seal band 200, and the positive charge is biased toward the upper surface (substrate W) of the dielectric portion of the electrostatic chuck 1111. Next, it is attracted by the biased charges, so electrons are supplied from the plasma to the substrate W and the substrate W is negatively charged. Then, the Coulomb force acts due to the potential difference between the upper surface of the seal band 200 (positive charge) and the back surface of the substrate W (negative charge), so the substrate W is adsorbed on the seal band 200. In this case, the first electrode layer 210 and the substrate W contact each other on the upper surface of the seal band 200, ensuring reliable electrical contact, and further ensuring the sealing performance of the first heat transfer space 202.

Similarly, in order to suppress the decrease in the adsorption force on the second electrode layer 212, it is preferable that the second electrode layer 212 is not provided on the entire surface of the edge ring mounting surface 111b. In detail, the second electrode layer 212 preferably has an area that does not overlap the second adsorption electrode layer 213 in a plan view. In this case, in the above-mentioned area, the Coulomb force may be applied by the fourth adsorption power supplied to the second adsorption electrode layer 213, so the edge ring 112 may be appropriately adsorbed and held on the edge ring mounting surface 111b.

Further, in view of suppressing the decrease in the adsorption force, it is preferable that the back surface of the edge ring 112 and the edge ring mounting surface 111b contact each other around the second electrode layer 212 contacting the edge ring 112. For example, when the second electrode layer 212 is provided on the upper surface of the seal band 203 of the edge ring mounting surface 111b, the second electrode layer 212 is provided at a center of the upper surface of the seal band 203 in a side view. In this case, the second electrode layer 212 and the edge ring 112 contact each other on the upper surface of the seal band 203, ensuring reliable electrical contact, and further ensuring the sealing performance of the second heat transfer space 204.

This embodiment may be applied even if the electrostatic chuck 1111 is a Johnson-Rahbeck (JR) type.

### (Increase in Adsorption Voltage and Simplification of Adsorption Power Source)

According to this embodiment, the first adsorption power source 33a is connected to the first electrode layer 210, and the second adsorption power source 33b is connected to the first adsorption electrode layer 211. Then, in a circuit shown in FIG. 6, the first adsorption power is supplied from the first adsorption power source 33a to the first electrode layer 210, and the first adsorption voltage A1 is applied when viewed from the ground potential. Further, the second adsorption power is supplied from the second adsorption power source 33b to the first adsorption electrode layer 211, and the second adsorption voltage A2 is applied when viewed from the ground potential. For example, assuming that the first adsorption voltage A1 is +3 kV and the second adsorption voltage A2 is −3 kV, the voltage of 6 kV(=|A1|+|A2|) may be generated in the substrate W and the first adsorption electrode layer 211. Therefore, by using two simple power sources, i.e. the first adsorption power source 33a and the second adsorption power source 33b, the adsorption force of the substrate W can be increased. In addition, since the adsorption force may be increased in this way, it is possible to reduce the leakage of the heat transfer gas from the first heat transfer space 202, and it is possible to reduce the temperature of the substrate W by increasing the pressure of the heat transfer gas, thereby improving the in-plane temperature uniformity of the substrate W.

Similarly, the third adsorption power source 33c is connected to the second electrode layer 212, and the fourth adsorption power source 33d is connected to the second adsorption electrode layer 213. In this case, the third adsorption power is supplied from the third adsorption power source 33c to the second electrode layer 212, and the third adsorption voltage A3 is applied when viewed from the ground potential. Further, the fourth adsorption power is supplied from the fourth adsorption power source 33d to the second adsorption electrode layer 213, and the fourth adsorption voltage A4 is applied when viewed from the ground potential. Then, a voltage that is the sum of |A3| and |A4| may be generated in the edge ring 112 and the second adsorption electrode layer 213. Therefore, by using two simple power sources, i.e. the third adsorption power source 33c and the fourth adsorption power source 33d, the adsorption force of the edge ring 112 can be increased.

According to this embodiment, the first bias RF power source 32a and the first adsorption power source 33a are connected to the first electrode layer 210, and the first bias RF power and the first adsorption power are supplied in a superimposed manner during processing. The second bias RF power source 32b and the third adsorption power source 33c are connected to the second electrode layer 212, and the second bias RF power and the third adsorption power are supplied in a superimposed manner.

### <Measures Against Abnormal Discharge>

In the plasma processing apparatus, there is a demand for improved high-power response in order to improve plasma processing productivity. For example, the bias power such as the bias RF power is increased. Further, as a countermeasure against the decrease in the adsorption force caused by the formation of the above-mentioned first and second electrode layers 210 and 212, it is also possible to increase the adsorption power. Under such a process with high power conditions, the abnormal discharge may undesirably occur in the through hole such as the first heat transfer gas supply hole 230a, the first pin insert hole 231a, the second heat transfer gas supply hole 233a, and the second pin insert hole 234a of the electrostatic chuck 1111.

### (Formation of First and Second Conductive Films)

In this embodiment, the first conductive film 232 is formed on the inner surface of the first heat transfer gas supply hole 230a and the inner surface of the first pin insert hole 231a to be electrically conductive to the first electrode layer 210. By the first electrode layer 210 and the first conductive film 232, the substrate W, the substrate mounting surface 111a, the first heat transfer gas supply hole 230a, and the first pin insert hole 231a have the same potential. Therefore, it is possible to suppress the above-mentioned abnormal discharge. As a result, high power can be achieved.

Similarly, the second conductive film 236 is formed on the inner surfaces of the second heat transfer gas supply holes 233a and 233b and the inner surfaces of the second pin insert holes 234a and 234b to be electrically conductive to the second electrode layer 212. By the second electrode layer 212 and the second conductive film 236, the edge ring 112, the edge ring mounting surface 111b, the second heat transfer gas supply holes 233a and 233b, and the second pin insert holes 234a and 234b have the same potential. Therefore, it is possible to suppress the above-mentioned abnormal discharge. As a result, high power can be achieved.

### (Short-Circuit Between Base and First Conductive Film)

According to this embodiment, the base 1110 includes the conductive member, and the first conductive film 232 is formed on the inner surface of the first heat transfer gas supply hole 230a and the inner surface of the first pin insert hole 231a as described above. Then, when the first conductive film 232 and the base 1110 are not short-circuited, the abnormal discharge may undesirably occur on the back surface of the substrate W and in the through hole such as the first heat transfer gas supply holes 230a and 230b and the first pin insert holes 231a and 231b due to a potential difference between the first conductive film 232 and the base 1110.

In this regard, according to this embodiment, the first conductive film 232 and the base 1110 are short-circuited to be electrically connected. Then, the first conductive film 232 and the base 1110 have the same potential, suppressing the above-mentioned abnormal discharge.

In this case, the source RF power is directly supplied to the substrate W via the base 1110, the first conductive film 232, and the first electrode layer 210 when processing. That is, the first bias RF power, the first adsorption power, and the source RF power are supplied to the first electrode layer 210 in a superimposed manner.

### (Insulating Material Formation for Base)

According to another embodiment, for example, when the base 1110 is formed of an insulating material such as alumina ceramics or silicon carbide, the abnormal discharge between the lower end (exit) of the through hole 220 and the base 1110 can be suppressed. In this embodiment, the insulating film 221 is omitted.

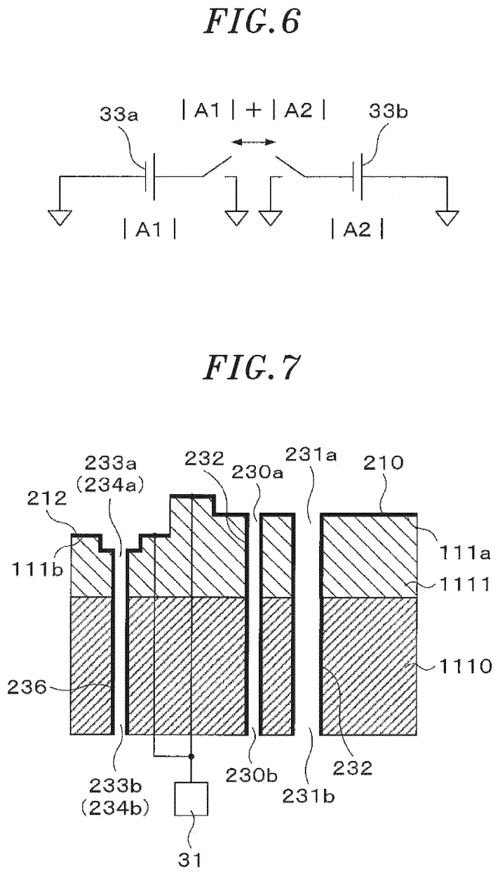

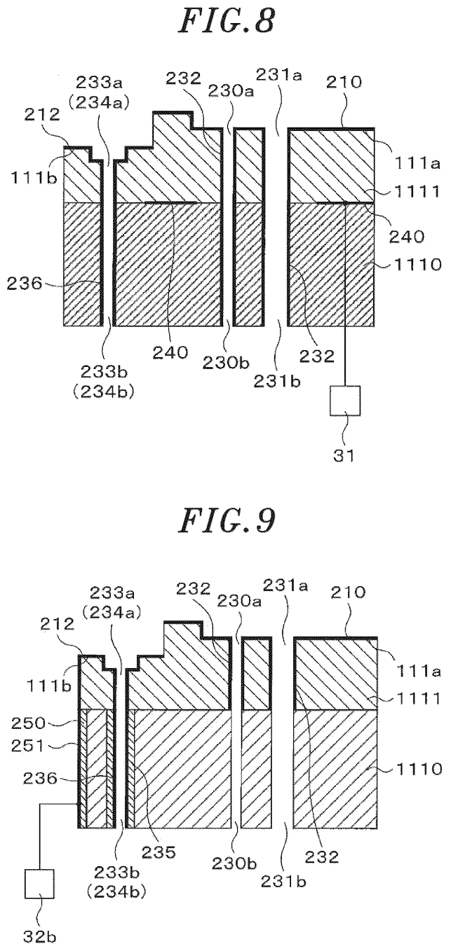

When the base 1110 is formed of the insulating material, as shown in FIGS. 7 and 8, the first conductive film 232 is formed from the upper end of the first heat transfer gas supply hole 230a to the lower end of the first heat transfer gas supply hole 230b on the inner surfaces of the first heat transfer gas supply hole 230a and the first heat transfer gas supply hole 230b. Further, the first conductive film 232 is formed from the upper end of the first pin insert hole 231a to the lower end of the first pin insert hole 231b on the inner surfaces of the first pin insert hole 231a and the first pin insert hole 231b.

Similarly to the above embodiment, the second conductive film 236 is formed from the upper end of the second heat transfer gas supply hole 233a to the lower end of the second heat transfer gas supply hole 233b on the inner surfaces of the second heat transfer gas supply hole 233a and the second heat transfer gas supply hole 233b. Further, the second conductive film 236 is formed from the upper end of the second pin insert hole 234a to the lower end of the second pin insert hole 234b on the inner surfaces of the second pin insert hole 234a and the second pin insert hole 234b. In this embodiment, the insulating film 235 is omitted.

When the base 1110 is formed of an insulating material, the source RF power is supplied through the following method, for example, because the base 1110 does not functions as the lower electrode. For example, as shown in FIG. 7, the source RF power source 31 may be electrically connected to the first electrode layer 210 and the second electrode layer 212. The source RF power is supplied to the first electrode layer 210 and the second electrode layer 212. Further, in this example, the source RF power source 31 may be provided with a first source RF power source connected to the first electrode layer 210, and a source RF power source connected to the second electrode layer 212.

For example, as shown in FIG. 8, a conductive bonding layer 240 may be provided between the base 1110 and the electrostatic chuck 1111. The source RF power source 31 is electrically connected to the conductive bonding layer 240, and the source RF power is supplied to the conductive bonding layer 240.

### (Elimination of Substrate Bias Terminal)

Conventionally, a terminal (hereinafter referred to as a “substrate bias terminal”) for supplying bias power such as the bias RF power to the substrate is provided on the substrate mounting surface of the electrostatic chuck. In order to provide this substrate bias terminal, it is necessary to form a space in the electrostatic chuck and form the insulating film such as glass on the inner surface of the space with an adhesive interposed therebetween. In this case, an air layer in this space may deteriorate heat removal during processing, and a temperature singularity (hot spot) may be undesirably formed on the substrate. In particular, the temperature singularity is likely to form in a high-input process using high power.

In this regard, according to this embodiment, the first conductive film 232 and the base 1110 are short-circuited, and the first bias RF power, the first adsorption power, and the source RF power are supplied to the first electrode layer 210 in a superimposed manner during plasma processing. In this case, the conventional substrate bias terminal is not required and may be omitted. Therefore, local deterioration of heat removal during the above-mentioned process is reduced, and the formation of the temperature singularity in the substrate W can be suppressed.

### (Elimination of Edge Ring Bias Terminal)

Conventionally, a terminal (hereinafter referred to as an “edge ring bias terminal”) for supplying bias power such as the bias RF power to the edge ring is provided on the edge ring mounting surface of the electrostatic chuck. In order to provide this edge ring bias terminal, it is necessary to form a space in the electrostatic chuck. Here, during processing, the electrostatic chuck is heated and cooled to expand and contract in a radial direction. Since there is a large difference in linear expansion coefficient between the dielectric material (e.g. ceramic) of the electrostatic chuck and the conductive material (e.g. aluminum) of the base, a difference in linear expansion between the electrostatic chuck and the base increases during processing. Further, since the edge ring bias terminal is provided on the outer peripheral side of the electrostatic chuck in a radial direction thereof, the influence of the linear expansion difference increases. Then, in order to avoid interference between the edge ring bias terminal and the electrostatic chuck, for example, it is necessary to provide flexibility to the edge ring bias terminal and to increase the space in which the edge ring bias terminal is provided. In this case, an air layer in this space may deteriorate heat removal during processing, and a temperature singularity (hot spot) may be undesirably formed on the substrate. In particular, the temperature singularity is likely to form in a high-input process using high power.

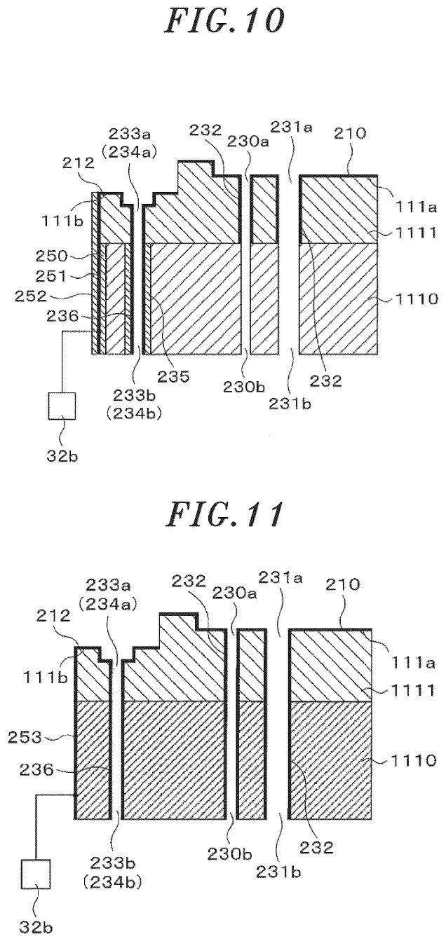

When the base 1110 includes the conductive member as in this embodiment, an insulating film 250 may be formed on the outer surface of the base 1110 as shown in FIGS. 9 and 10. The insulating film 250 is formed, for example, by thermal spraying. The insulating film 250 can reduce power loss from the outer surface of the base 1110 to the outside of the electrostatic chuck 1111, and can also suppress the abnormal discharge between the base 1110 and surrounding components.

As measures against the above-mentioned temperature singularity, a conductive film 251 is provided on the surface of the insulating film 250 as shown in FIG. 9. The conductive film 251 is electrically conductive to the second electrode layer 212. Further, the conductive film 251 is electrically connected to the second bias RF power source 32b. Then, the second bias RF power from the second bias RF power source 32b is supplied via the conductive film 251 to the second electrode layer 212. In this case, the conventional edge ring bias terminal is not required and may be omitted. Therefore, local deterioration of heat removal during the above-mentioned process is reduced, and the formation of the temperature singularity in the substrate W can be suppressed.

Further, as shown in FIG. 10, the insulating film 252 may be formed on the surface of the conductive film 251. The insulating film 252 is formed, for example, by thermal spraying. In this case, it is possible to suppress the abnormal discharge between the base 1110 and surrounding components. Further, when the conductive film 251 is formed of, for example, metal, metal contamination within the plasma processing chamber 10 due to the consumption of the conductive film 251 can also be suppressed by the insulating film 252.

In another embodiment, when the base 1110 is formed of an insulating material, a conductive film 253 is provided on the side surface of the base 1110, as shown in FIG. 11, as a countermeasure against the above-mentioned temperature singularity. Similarly to the conductive film 251, the conductive film 253 is electrically conductive to the second electrode layer 212, and is electrically connected to the second bias RF power source 32b. Then, the second bias RF power from the second bias RF power source 32b is supplied to the second electrode layer 212 via the conductive film 253. In this case, the conventional edge ring bias terminal is not required and may be omitted. Further, the formation of the temperature singularity in the substrate W can be suppressed.

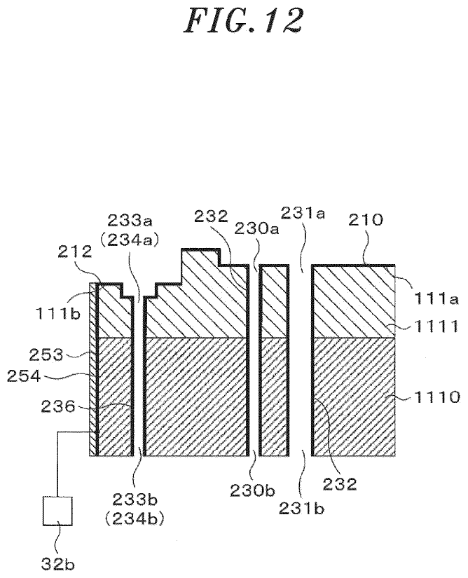

Similarly to the insulating film 252, as shown in FIG. 12, the insulating film 254 may be formed on the surface of the conductive film 253. The insulating film 254 is formed, for example, by thermal spraying. In this case, it is possible to suppress the abnormal discharge between the base 1110 and surrounding components. Further, when the conductive film 253 is formed of, for example, metal, metal contamination within the plasma processing chamber 10 due to the consumption of the conductive film 253 can also be suppressed by the insulating film 254.

### <Measures to Reduce Bias in Plasma Distribution>

When the base includes the conductive member and the source RF power is supplied to the lower electrode of the base, the source RF power supplied to the lower electrode escapes into the plasma processing space through the electrostatic chuck. For example, in the case of a so-called hat-shaped electrostatic chuck where the edge ring mounting surface is lower than the substrate mounting surface and the dielectric portion of the edge ring side is thinner than that of the substrate side, the impedance on the edge ring mounting surface is smaller than that on the substrate side. In this case, a large amount of the source RF power escapes from the edge ring side, causing variation between the source RF power on the substrate side and the source RF power on the edge ring side. Thus, conventionally, a spraying film for adjusting impedance is formed directly under the edge ring mounting surface to suppress power loss from the edge ring side.

In this regard, according to this embodiment, when the source RF power source 31 is connected to the second electrode layer 212 formed on the edge ring mounting surface 111b as described above, the source RF power is directly supplied to the second electrode layer 212. For this reason, it is not possible to use a conventional thermal spraying structure for adjusting impedance. Thus, it is preferable to provide an impedance adjustment part inside the power supply line to the second electrode layer 212. As an example of the impedance adjustment part, for example, a vacuum variable capacitor is used. In this case, variation between the source RF power supplied to the first electrode layer 210 and the source RF power supplied to the second electrode layer 212 can be suppressed. As a result, bias in plasma distribution can be reduced.

### <Measures to Reduce Bias in Ion Sheath Thickness>

Similarly to the measures against the above-mentioned variation in source RF power (biased plasma distribution), measures against variation in bias RF power (biased ion sheath thickness) are also required. For example, when the bias electrode is provided in the electrostatic chuck and the bias RF power is supplied to the bias electrode, the bias RF power supplied to the bias electrode escapes into the plasma processing space through the electrostatic chuck. In the case of a hat-shaped electrostatic chuck, the impedance on the edge ring mounting surface is smaller than that on the substrate side. In this case, a large amount of the bias RF power escapes from the edge ring side, causing variation between the bias RF power on the substrate side and the bias RF power on the edge ring side.

In this regard, according to this embodiment, since the bias RF power is directly supplied to the second electrode layer 212, it is not possible to use a conventional thermal spraying structure for adjusting impedance. Thus, it is preferable to provide an impedance adjustment part inside the power supply line to the second electrode layer 212. As an example of the impedance adjustment part, for example, a vacuum variable capacitor is used. In this case, variation between the bias RF power supplied to the first electrode layer 210 and the bias RF power supplied to the second electrode layer 212 can be suppressed. As a result, bias in ion sheath thickness can be reduced.

### <Specific Arrangement of First and Second Electrode Layers>

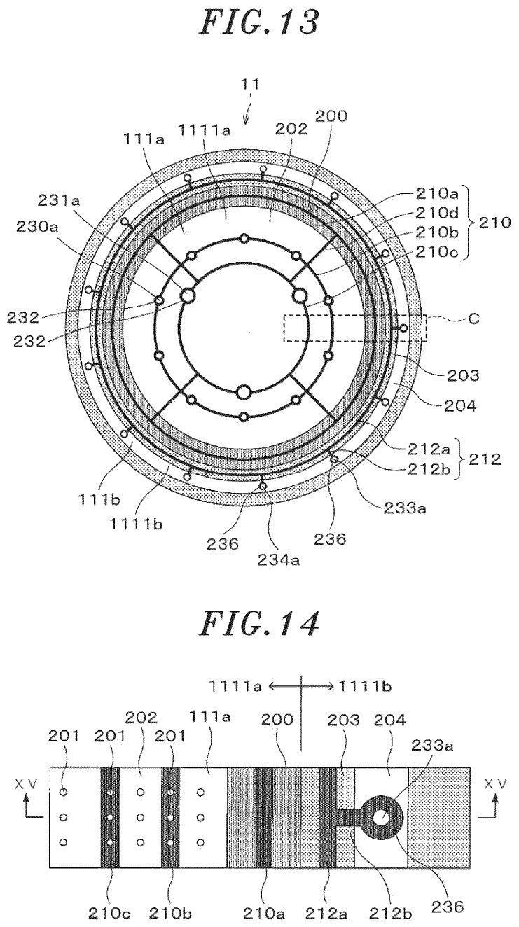

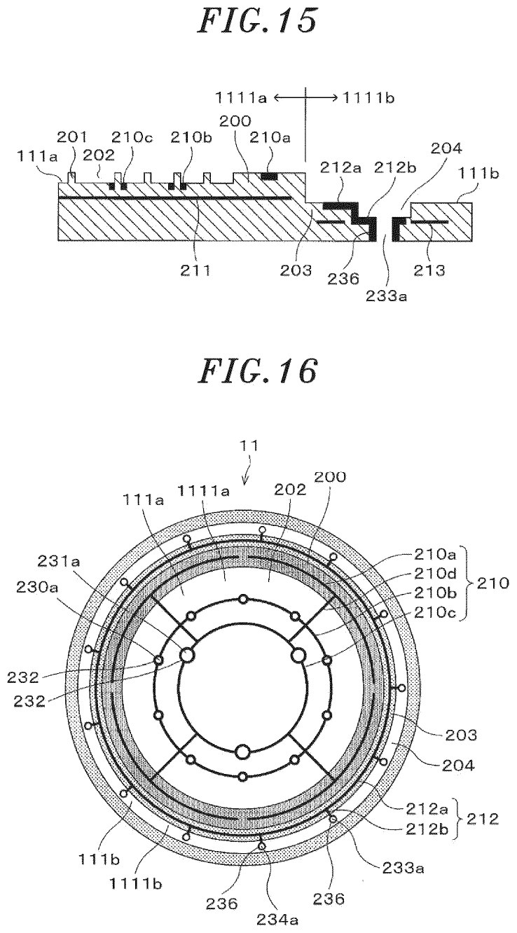

Next, the specific arrangement of the first electrode layer 210 and the second electrode layer 212 will be described. FIG. 13 is a plan view illustrating the arrangement of the first electrode layer 210 and the second electrode layer 212. FIG. 14 is an enlarged plan view illustrating a portion (portion C shown by the dotted line) of FIG. 13. FIG. 15 is a sectional view taken along line XV-XV of FIG. 14.

The substrate mounting surface 111a of the substrate mounting portion 1111a includes the seal band 200 and the plurality of dots 201. The edge ring mounting surface 111b of the edge ring mounting portion 1111b includes the seal band 203.

The first electrode layer 210 has a triple structure in which annular first electrode layers 210a, 210b, and 210c are provided from the outside in a radial direction. Further, the first electrode layer 210 is electrically conductive to the first electrode layers 210a, 210b, and 210c, and has a plurality of first electrode layers 210d extending in the radial direction. Although the first electrode layers 210d are provided at four locations in the example shown in FIG. 13, the number of the first electrode layers 210d is not limited thereto.

The first electrode layer 210a is provided in an annular shape at the center on the upper surface of the seal band 200 as shown in FIG. 5. The reason why it is preferable to provide the first electrode layer at the center on the upper surface of the seal band 200 is as described above. The first electrode layer 210a contacts the back surface of the substrate W. That is, in the first electrode layer 210, power is supplied to the substrate W via the first electrode layer 210a. In order to ensure reliable contact between the first electrode layer 210a and the substrate W, the first electrode layer 210a may protrude beyond the upper surface of the surrounding seal band 200.

In the first heat transfer space 202 on the radially inner side of the seal band 200, a plurality of first heat transfer gas supply holes 230a are provided at equal intervals on the same circumference. The first electrode layer 210b is annularly provided on the same circumference as the plurality of first heat transfer gas supply holes 230a. Further, the first electrode layer 210b is electrically conductive to the first conductive film 232 provided on the inner surface of each first heat transfer gas supply hole 230a.

Inside the plurality of first heat transfer gas supply holes 230a in the radial direction, a plurality of first pin insert holes 231a are provided at equal intervals on the same circumference. The first electrode layer 210c is annularly provided on the same circumference as the plurality of first pin insert holes 231a. Further, the first electrode layer 210c is electrically conductive to the first conductive film 232 provided on the inner surface of each first pin insert hole 231a.

If the first electrode layer 210 is provided on the upper surface of the dot 201, the adsorption force of the substrate W on the first electrode layer 210 is reduced as described above. Therefore, in this embodiment, the first electrode layers 210b, 210c, and 210d are not provided on the upper surface of the dot 201. Further, although the first electrode layers 210b and 210c are provided around the dot 201 in the example shown in FIGS. 14 and 15, they may be provided between the dots 201.

The second electrode layer 212 includes an annular second electrode layer 212a, and a second electrode layer 212b for electrically connecting the second electrode layer 212a and the second conductive film 236.

The second electrode layer 212a is provided in an annular shape at the center on the upper surface of the seal band 203. The reason why it is preferable to provide the second electrode layer at the center on the upper surface of the seal band 203 is as described above. The second electrode layer 212a contacts the back surface of the edge ring 112. That is, in the second electrode layer 212, power is supplied to the edge ring 112 via the second electrode layer 212a. In order to ensure reliable contact between the second electrode layer 212a and the edge ring 112, the second electrode layer 212a may protrude beyond the upper surface of the surrounding seal band 203.

In the second heat transfer space 204 on the radially outer side of the seal band 203, a plurality of second heat transfer gas supply holes 233a and a plurality of second pin insert holes 234a are provided at equal intervals on the same circumference. The second electrode layer 212b extends radially from the second electrode layer 212, and is electrically conductive to the second conductive film 236 provided on the inner surface of each second heat transfer gas supply hole 233a and the inner surface of the second pin insert hole 234a.

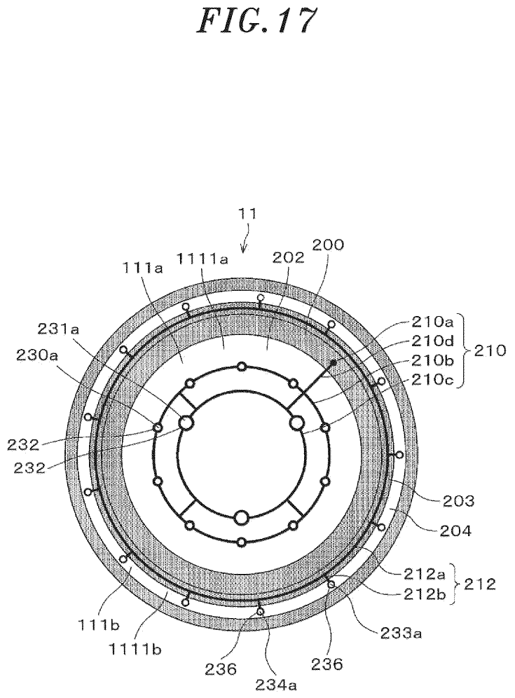

The above embodiment is an example of the arrangement of the first electrode layer 210 and the second electrode layer 212, and the arrangement of the first electrode layer 210 and the second electrode layer 212 may be optionally set. For example, as shown in FIG. 16, the first electrode layer 210a on the seal band 200 may be divided. Further, for example, as shown in FIG. 17, the first electrode layer 210a on the seal band 200 may be provided at one point. However, in view of the in-plane plasma processing uniformity of the substrate, it is preferable that the first electrode layer 210 and the second electrode layer 212 be arranged symmetrically.

### <Adsorption Sequence>

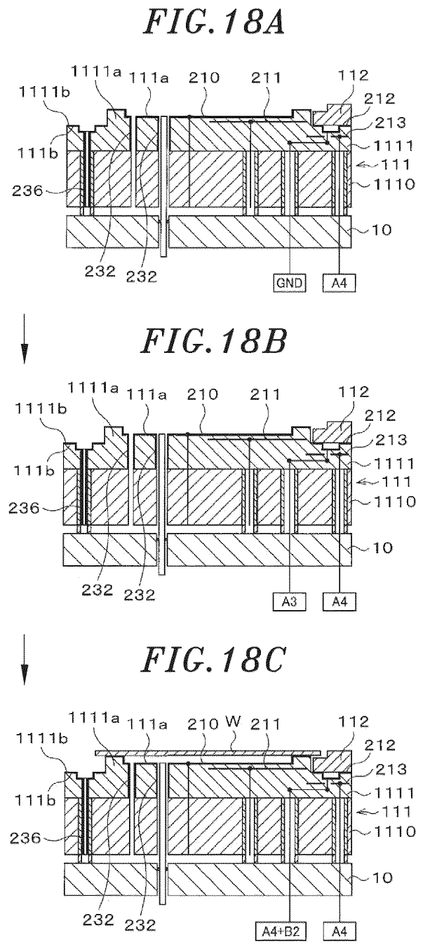

Next, an example of the adsorption sequence in this embodiment will be described. FIG. 18 is an explanatory diagram illustrating an example of the adsorption sequence of the edge ring 112.

### (Step S1: Temporary Adsorption)

First, in step S1, the temporary adsorption of the edge ring 112 is performed. As shown in FIG. 18(a), in the temporary adsorption, fourth adsorption power is supplied from the fourth adsorption power source 33d to the second adsorption electrode layer 213, and a fourth adsorption voltage A4, for example, +3 kV is applied. Then, due to the dielectric polarization of the edge ring mounting portion 1111b of the electrostatic chuck 1111, the edge ring mounting surface 111b side of the edge ring mounting portion 1111b is positively charged.

Further, the second electrode layer 212 is connected to the ground potential. Then, it is attracted by the positive charge on the edge ring mounting surface 111b side of the edge ring mounting portion 1111b, so electrons are supplied from the plasma to the edge ring 112 and the edge ring 112 is negatively charged. The Coulomb force acts due to the potential difference between the edge ring mounting surface 111b (positive charge) and the back surface of the edge ring 112 (negative charge), so the edge ring 112 is temporarily adsorbed on the edge ring mounting surface 111b.

Further, the method of temporarily adsorbing the edge ring 112 is not limited to this embodiment. For example, the fourth adsorption power may be supplied to the second adsorption electrode layer 213, the fourth adsorption voltage A4 may be applied thereto, and the second electrode layer 212 may be connected to a floating potential. When the inside of the plasma processing chamber 10 is maintained at a constant pressure with gas, electrons are supplied from the plasma processing chamber 10 connected to the ground potential to the edge ring 112 via the gas. Then, the Coulomb force acts due to the potential difference between the edge ring mounting surface 111b (positive charge) and the back surface of the edge ring 112 (negative charge), so the edge ring 112 is temporarily adsorbed on the edge ring mounting surface 111b.

In order to prevent the edge ring 112 from moving when the inside of the plasma processing chamber 10 is evacuated from an atmospheric atmosphere to a vacuum atmosphere, it is necessary to adsorb the edge ring 112 even under atmospheric conditions. For this reason, the temporary adsorption is performed before main adsorption.

### (Step S2: Main Adsorption)

Next, in step S2, the main adsorption of the edge ring 112 is performed. As described above, since the adsorption force of the edge ring 112 decreases on the second electrode layer 212, the main adsorption of the edge ring 112 is performed.

As shown in FIG. 18(b), in the main adsorption, the fourth adsorption power source 33d continues to supply the fourth adsorption power to the second adsorption electrode layer 213, and the fourth adsorption voltage A4, for example, +3 kV is applied. Further, the third adsorption power source 33c supplies the third adsorption power to the second electrode layer 212, and the third adsorption voltage A3, for example, −3 kV is applied. Then, the voltage of 6 kV (=|A3+|A4) may be generated in the edge ring 112 and the second adsorption electrode layer 213. Therefore, by using two simple power sources, i.e. the third adsorption power source 33c and the fourth adsorption power source 33d, the adsorption force of the edge ring 112 can be increased.

### (Step S3: Plasma Processing)

Next, in step S3, plasma processing is performed. As shown in FIG. 18(c), the main adsorption is continued during plasma processing. That is, the fourth adsorption power source 33d continues to supply the fourth adsorption power to the second adsorption electrode layer 213, and the fourth adsorption voltage A4, for example, +3 kV is applied. Further, the third adsorption power source 33c continues to supply the third adsorption power to the second electrode layer 212, and the third adsorption voltage A3, for example, −3 kV is applied.

Further, during plasma processing, the second bias RF power source 32b supplies the second bias RF power to the second electrode layer 212, and the second bias RF voltage B2 is applied. That is, the second bias RF power and the third adsorption power are supplied to the second electrode layer 212 in a superimposed manner.

Further, the source RF power for generating plasma may be supplied from the source RF power source 31 to the lower electrode of the base 1110, or may be supplied from the source RF power source 31 to the second electrode layer 212. In the latter case, the second bias RF power, the third adsorption power, and the source RF power are supplied to the second electrode layer 212 in a superimposed manner.

Further, the adsorption sequence for the substrate W is the same as the adsorption sequence for the edge ring 112 described above. That is, in the temporary adsorption of step S1, the second adsorption power is supplied from the second adsorption power source 33b to the first adsorption electrode layer 211, and the second adsorption voltage A2 is applied. Further, the first electrode layer 210 is connected to the ground potential. Then, the Coulomb force acts due to the potential difference between the substrate mounting surface 111a (positive charge) and the back surface of the substrate W (negative charge), so the substrate is temporarily adsorbed on the substrate mounting surface 111a.

Next, in the main adsorption of step S2, the second adsorption power continues to be supplied from the second adsorption power source 33b to the first adsorption electrode layer 211, and the second adsorption voltage A2 is applied. Further, the first adsorption power is supplied from the first adsorption power source 33a to the first electrode layer 210, and the first adsorption voltage A1 is applied. Then, the voltage that is the sum of |A1| and |A2| may be generated in the substrate W and the first adsorption electrode layer 211. Therefore, the adsorption force for the substrate W can be increased.

Next, in the plasma processing of step S3, the main adsorption of the substrate W is continued. That is, the second adsorption power continues to be supplied from the second adsorption power source 33b to the first adsorption electrode layer 211, and the second adsorption voltage A2 is applied. Further, the first adsorption power continues to be supplied from the first adsorption power source 33a to the first electrode layer 210, and the first adsorption voltage A1 is applied.

Further, during plasma processing, the first bias RF power source 32a supplies the first bias RF power to the first electrode layer 210, and the first bias RF voltage B1 is applied. That is, the first bias RF power and the first adsorption power are supplied to the first electrode layer 210 in a superimposed manner.

Further, the source RF power for generating plasma may be supplied from the source RF power source 31 to the base 1110, or may be supplied from the source RF power source 31 to the first electrode layer 210. In the latter case, the first bias RF power, the first adsorption power, and the source RF power are supplied to the first electrode layer 210 in a superimposed manner.

The adsorption sequence is not limited to this embodiment. Hereinafter, various examples of adsorption sequences will be described. In the first to third examples below, the time axis is also described for comparison.

### First Example of Adsorption Sequence

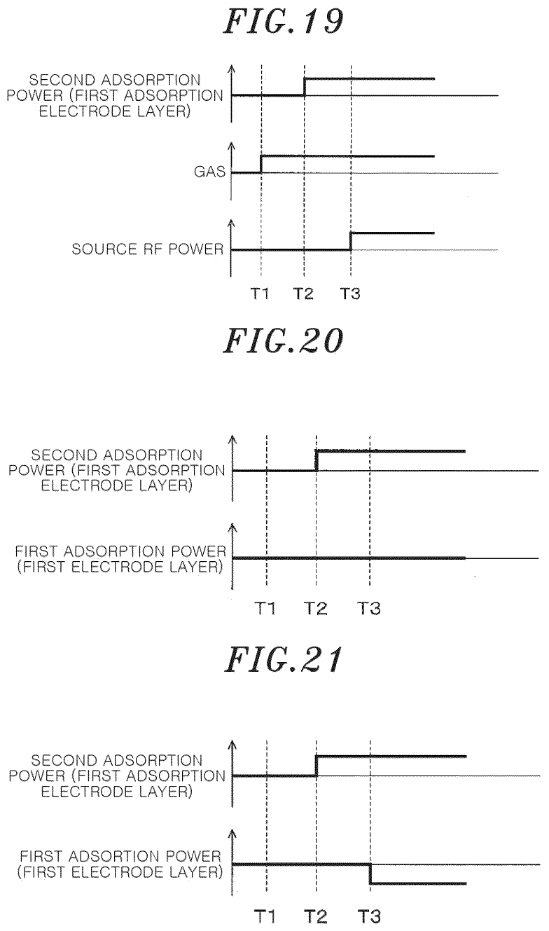

As shown in FIG. 19, in the first example, gas is first supplied into the plasma processing chamber 10 (time T1).

Next, the second adsorption power is supplied from the second adsorption power source 33b to the first adsorption electrode layer 211 (time T2). At time T2, electrons are supplied to the edge ring from the plasma processing chamber 10, which is connected to the ground potential, via the gas. Further, the Coulomb force acts due to the potential difference between the substrate mounting surface 111a (positive charge) and the back surface of the substrate W (negative charge), so the substrate W is temporarily adsorbed on the substrate mounting surface 111a. In this temporary adsorption, few electrons are supplied to the substrate W, and the adsorption force is small.

Next, the source RF power is supplied from the source RF power source 31 to the lower electrode of the base 1110 (time T3). At time T3, the plasma is generated, and electrons are supplied from the plasma to the substrate W. Further, the Coulomb force acts due to the potential difference between the substrate mounting surface 111a (positive charge) and the back surface of the substrate W (negative charge), so the main adsorption of the substrate W on the substrate mounting surface 111a is performed. In this main adsorption, a sufficient amount of electrons are supplied to the substrate W, and the adsorption force is large.

### Second Example of Adsorption Sequence

As shown in FIG. 20, in the second example, the second adsorption power is first supplied from the second adsorption power source 33b to the first adsorption electrode layer 211 (time T2). At time T2, the first electrode layer 210 is connected to the ground potential. Then, electrons are supplied from the ground potential to the substrate W, and the substrate W is negatively charged. Further, the Coulomb force acts due to the potential difference between the substrate mounting surface 111a (positive charge) and the back surface of the substrate W (negative charge), so the main adsorption of the substrate W on the substrate mounting surface 111a is performed. The main adsorption of the substrate W at this time T2 is the same as the temporary adsorption of step S1 in the above embodiment shown in FIG. 18.

In such a case, unlike the first example, the main adsorption of the substrate W may be performed without depending on gas or source RF power.

In the second example, the adsorption sequence for the edge ring 112 is also the same as the adsorption sequence for the substrate W.

### Third Example of Adsorption Sequence

In the third example shown in FIG. 21, the second adsorption power is first supplied from the second adsorption power source 33b to the first adsorption electrode layer 211 (time T2). At time T2, the first electrode layer 210 is connected to the ground potential. Then, similarly to the second example, the main adsorption of the substrate Won the substrate mounting surface 111a is performed.

Next, the first adsorption power is supplied from the first adsorption power source 33a to the first electrode layer 210 (time T3). The first adsorption voltage applied by the first adsorption power and the second adsorption voltage applied by the second adsorption power have opposite polarities. In this way, the potential difference between the substrate mounting surface 111a (positive charge) and the back surface of the substrate W (negative charge) may be magnified, and the adsorption force for the substrate W may be increased. The adsorption of the substrate W at this time T3 is the same as the main adsorption of step S2 in the above embodiment shown in FIG. 18.

In the third example, the adsorption sequence for the edge ring 112 is also the same as the adsorption sequence for the substrate W.

The embodiments disclosed herein should be considered to be illustrative in all respects and not restrictive. The above-described embodiments may be omitted, replaced, or modified in various forms without departing from the scope and spirit of the appended claims. For example, any combination of the components of the above embodiments is possible. This combination naturally provides the actions and effects of the respective components, as well as other actions and effects that are obvious to those skilled in the art from the description of this specification.

Further, the effects described in this specification are merely explanatory or illustrative and are not restrictive. That is, the technology according to the present disclosure may have other effects that are obvious to those skilled in the art from the description of this specification, in addition to or in place of the above effects.

It should be noted that the following configuration examples also fall within the technical scope of the present disclosure.

(1)

A plasma processing apparatus comprising:
a plasma processing chamber;
a base disposed in the plasma processing chamber;
an electrostatic chuck disposed on the base, and comprising a substrate mounting portion, and an edge ring mounting portion on which an edge ring surrounding a substrate mounted on the substrate mounting portion is mounted; and
at least one of a first power supply part that supplies power to the substrate mounting portion and a second power supply part that supplies power to the edge ring mounting portion,
wherein the first power supply part comprises:
a first electrode layer formed on a substrate mounting surface of the substrate mounting portion;
a first adsorption electrode layer disposed under the first electrode layer in the substrate mounting portion; and
a first bias power source electrically connected to the first electrode layer, and
wherein the second power supply part comprises:
a second electrode layer formed on an edge ring mounting surface of the edge ring mounting portion;
a second adsorption electrode layer disposed under the second electrode layer in the edge ring mounting portion; and
a second bias power source electrically connected to the second electrode layer.

(2)

The plasma processing apparatus of (1), wherein the first electrode layer has an area that does not overlap the first adsorption electrode layer, in a plan view.

(3)

The plasma processing apparatus of (1) or (2), wherein the second electrode layer has an area that does not overlap the second adsorption electrode layer, in a plan view.

(4)

The plasma processing apparatus of any one of (1) to (3), wherein the first electrode layer is formed on an outer peripheral side of the substrate mounting surface.

(5)

The plasma processing apparatus of (4), wherein the first electrode layer is formed at a center of an upper surface of a seal band of the substrate mounting surface, in a side view.

(6)

The plasma processing apparatus of any one of (1) to (5), wherein the first electrode layer comprises a first adsorption power source electrically connected to the first electrode layer.

(7)

The plasma processing apparatus of (6), wherein the first electrode layer comprises a second adsorption power source electrically connected to the first adsorption electrode layer.

(8)

The plasma processing apparatus of any one of (1) to (7), wherein the first power supply part comprises a first plasma generating power source electrically connected to the first electrode layer.

(9)

The plasma processing apparatus of any one of (1) to (8), wherein the second power supply part comprises a third adsorption power source electrically connected to the second electrode layer.

(10)

The plasma processing apparatus of (9), wherein the second power supply part comprises a fourth adsorption power source electrically connected to the second adsorption electrode layer.

(11)

The plasma processing apparatus of any one of (1) to (10), wherein the second power supply part comprises a second plasma generating power source electrically connected to the second electrode layer.

(12)

The plasma processing apparatus of any one of (1) to (11), wherein the substrate mounting portion comprises at least one first through hole, and
a first conductive film is formed on an inner surface of the first through hole to be electrically conductive to the first electrode layer.

(13)

The plasma processing apparatus of (12), wherein the base is formed of a conductive material, and
the base and the first conductive film are electrically connected to each other.

(14)

The plasma processing apparatus of any one of (1) to (13), wherein the edge ring mounting portion comprises at least one second through hole, and
a second conductive film is formed on an inner surface of the second through hole to be electrically conductive to the second electrode layer.

(15)

An electrostatic chuck comprising:
a dielectric portion comprising a substrate mounting portion and an edge ring mounting portion on which an edge ring surrounding a substrate mounted on the substrate mounting portion is mounted; and
at least one of a first electrode part provided at the substrate mounting portion and a second electrode part provided at the edge ring mounting portion,
wherein the first electrode part comprises:
a first bias electrode layer formed on a substrate mounting surface of the substrate mounting portion; and
a first adsorption electrode layer disposed under the first bias electrode layer in the substrate mounting portion, and
wherein the second electrode part comprises:
a second bias electrode layer formed on an edge ring mounting surface of the edge ring mounting portion; and
a second adsorption electrode layer disposed under the second bias electrode layer in the edge ring mounting portion.

(16)

The electrostatic chuck of (15), wherein the first bias electrode layer has an area that does not overlap the first adsorption electrode layer, in a plan view.

(17)

The electrostatic chuck of (15) or (16), wherein the second bias electrode layer has an area that does not overlap the second adsorption electrode layer, in a plan view.

(18)

The electrostatic chuck of any one of (15) to (17), wherein the first bias electrode layer is formed on an outer peripheral side of the substrate mounting surface.

(19)

The electrostatic chuck of (18), wherein the first bias electrode layer is formed at a center of an upper surface of a seal band of the substrate mounting surface, in a side view.

(20)

The electrostatic chuck of any one of (15) to (19), wherein the substrate mounting portion comprises at least one first through hole, and
a first conductive film is formed on an inner surface of the first through hole to be electrically conductive to the first electrode layer.

(21)

The electrostatic chuck of any one of (15) to (20), wherein the edge ring mounting portion comprises at least one second through hole, and
a second conductive film is formed on an inner surface of the second through hole to be electrically conductive to the second electrode layer.

(22)

A plasma processing method using a plasma processing apparatus, wherein the plasma processing apparatus comprises:
a plasma processing chamber;
a base disposed in the plasma processing chamber;
an electrostatic chuck disposed on the base, and comprising a substrate mounting portion, and an edge ring mounting portion on which an edge ring surrounding a substrate mounted on the substrate mounting portion is mounted;
an electrode layer formed on a substrate mounting surface of the substrate mounting portion;
an adsorption electrode layer disposed under the electrode layer in the substrate mounting portion;
a bias power source electrically connected to the electrode layer;
a first adsorption power source electrically connected to the electrode layer; and a second adsorption power source electrically connected to the adsorption electrode layer,
wherein the plasma processing method comprises:
a process of temporarily adsorbing a substrate on the substrate mounting portion, by supplying second adsorption power from the second adsorption power source to the adsorption electrode layer;
a process of mainly adsorbing the substrate on the substrate mounting portion, by supplying first adsorption power from the first adsorption power source to the electrode layer, and supplying the second adsorption power from the second adsorption power source to the adsorption electrode layer; and
a process of performing plasma processing on the substrate, by supplying bias power from the bias power source to the electrode layer.

1. A plasma processing apparatus comprising:
a plasma processing chamber;
a base disposed in the plasma processing chamber;
an electrostatic chuck disposed on the base, and comprising a substrate mounting portion, and an edge ring mounting portion on which an edge ring surrounding a substrate mounted on the substrate mounting portion is mounted; and
at least one of a first power supply part that supplies power to the substrate mounting portion and a second power supply part that supplies power to the edge ring mounting portion,
wherein the first power supply part comprises:
a first electrode layer formed on a substrate mounting surface of the substrate mounting portion;
a first adsorption electrode layer disposed under the first electrode layer in the substrate mounting portion; and
a first bias power source electrically connected to the first electrode layer, and
wherein the second power supply part comprises:
a second electrode layer formed on an edge ring mounting surface of the edge ring mounting portion;
a second adsorption electrode layer disposed under the second electrode layer in the edge ring mounting portion; and
a second bias power source electrically connected to the second electrode layer.

2. The plasma processing apparatus of claim 1, wherein the first electrode layer has an area that does not overlap the first adsorption electrode layer, in a plan view.

3. The plasma processing apparatus of claim 1, wherein the second electrode layer has an area that does not overlap the second adsorption electrode layer, in a plan view.

4. The plasma processing apparatus of claim 1, wherein the first electrode layer is formed on an outer peripheral side of the substrate mounting surface.

5. The plasma processing apparatus of claim 4, wherein the first electrode layer is formed at a center of an upper surface of a seal band of the substrate mounting surface, in a side view.

6. The plasma processing apparatus of claim 1, wherein the first electrode layer comprises a first adsorption power source electrically connected to the first electrode layer.

7. The plasma processing apparatus of claim 6, wherein the first electrode layer comprises a second adsorption power source electrically connected to the first adsorption electrode layer.

8. The plasma processing apparatus of claim 1, wherein the first power supply part comprises a first plasma generating power source electrically connected to the first electrode layer.

9. The plasma processing apparatus of claim 1, wherein the second power supply part comprises a third adsorption power source electrically connected to the second electrode layer.

10. The plasma processing apparatus of claim 9, wherein the second power supply part comprises a fourth adsorption power source electrically connected to the second adsorption electrode layer.

11. The plasma processing apparatus of claim 1, wherein the second power supply part comprises a second plasma generating power source electrically connected to the second electrode layer.

12. The plasma processing apparatus of claim 1, wherein the substrate mounting portion comprises at least one first through hole, and
a first conductive film is formed on an inner surface of the first through hole to be electrically conductive to the first electrode layer.

13. The plasma processing apparatus of claim 12, wherein the base is formed of a conductive material, and
the base and the first conductive film are electrically connected to each other.

14. The plasma processing apparatus of claim 1, wherein the edge ring mounting portion comprises at least one second through hole, and
a second conductive film is formed on an inner surface of the second through hole to be electrically conductive to the second electrode layer.

15. An electrostatic chuck comprising:
a dielectric portion comprising a substrate mounting portion and an edge ring mounting portion on which an edge ring surrounding a substrate mounted on the substrate mounting portion is mounted; and
at least one of a first electrode part provided at the substrate mounting portion and a second electrode part provided at the edge ring mounting portion,
wherein the first electrode part comprises:
a first bias electrode layer formed on a substrate mounting surface of the substrate mounting portion; and
a first adsorption electrode layer disposed under the first bias electrode layer in the substrate mounting portion, and
wherein the second electrode part comprises:
a second bias electrode layer formed on an edge ring mounting surface of the edge ring mounting portion; and
a second adsorption electrode layer disposed under the second bias electrode layer in the edge ring mounting portion.

16. The electrostatic chuck of claim 15, wherein the first bias electrode layer has an area that does not overlap the first adsorption electrode layer, in a plan view.

17. The electrostatic chuck of claim 15, wherein the second bias electrode layer has an area that does not overlap the second adsorption electrode layer, in a plan view.

18. The electrostatic chuck of claim 15, wherein the first bias electrode layer is formed on an outer peripheral side of the substrate mounting surface.

19. The electrostatic chuck of claim 18, wherein the first bias electrode layer is formed at a center of an upper surface of a seal band of the substrate mounting surface, in a side view.

20. The electrostatic chuck of claim 15, wherein the substrate mounting portion comprises at least one first through hole, and
a first conductive film is formed on an inner surface of the first through hole to be electrically conductive to the first electrode layer.

21. The electrostatic chuck of claim 15, wherein the edge ring mounting portion comprises at least one second through hole, and
a second conductive film is formed on an inner surface of the second through hole to be electrically conductive to the second electrode layer.

22. A plasma processing method using a plasma processing apparatus, wherein the plasma processing apparatus comprises:
a plasma processing chamber;
a base disposed in the plasma processing chamber;
an electrostatic chuck disposed on the base, and comprising a substrate mounting portion, and an edge ring mounting portion on which an edge ring surrounding a substrate mounted on the substrate mounting portion is mounted;
an electrode layer formed on a substrate mounting surface of the substrate mounting portion;
an adsorption electrode layer disposed under the electrode layer in the substrate mounting portion;
a bias power source electrically connected to the electrode layer;
a first adsorption power source electrically connected to the electrode layer; and
a second adsorption power source electrically connected to the adsorption electrode layer,
wherein the plasma processing method comprises:
a process of temporarily adsorbing a substrate on the substrate mounting portion, by supplying second adsorption power from the second adsorption power source to the adsorption electrode layer;
a process of mainly adsorbing the substrate on the substrate mounting portion, by supplying first adsorption power from the first adsorption power source to the electrode layer, and supplying the second adsorption power from the second adsorption power source to the adsorption electrode layer; and
a process of performing plasma processing on the substrate, by supplying bias power from the bias power source to the electrode layer.
